(19) United States
(12) Patent Application Publication
(10) Pub. No.: US 2026/0247746 A1
(43) Pub. Date: Aug. 20, 2026

(54) SOLAR CELL MODULE

(71) Applicant: KANEKA CORPORATION, Osaka (JP)

(72) Inventors: Junichi NAKAMURA, Settsu-shi (JP); Toru TERASHITA, Settsu-shi (JP); Kohei KOJIMA, Settsu-shi (JP)

(73) Assignee: KANEKA CORPORATION, Osaka (JP)

(21) Appl. No.: 19/647,000

(22) Filed: Apr. 14, 2026

Related U.S. Application Data
(63) Continuation of application No. PCT/JP2024/037137, filed on Oct. 18, 2024.

(30) Foreign Application Priority Data
Oct. 19, 2023 (JP) 2023-180228

(51) Int. Cl. H10F 77/70; H10F 19/20

(52) U.S. Cl. CPC H10F 77/707; H10F 19/20

(57) ABSTRACT

A solar cell module in which a non-power generation region is not formed at the center comprises first and second thin-film solar cell submodules having first and second integrated structures, respectively, and which are adjacent to each other in a first direction on a transparent substrate. The first and second integrated structures each has a first separation groove separating a first transparent electrode layer in the first direction; a second separation groove separating a second conductivity-type charge transport layer, a photoelectric conversion layer, and a first conductivity-type charge transport layer in the first direction; and a third separation groove separating a second electrode layer in the first direction. The first and second integrated structures are line-symmetric structures and thus, the third, second and first separation grooves are arranged in this order in the first direction from the center between the first and second integrated structures toward both ends.

### CROSS-REFERENCE TO RELATED APPLICATIONS

This application claims benefit of priority to International Patent Application No. PCT/JP 2024/037137, filed Oct. 18, 2024, and to Japanese Patent Application No. 2023-180228, filed Oct. 19, 2023, the entire contents of each are incorporated herein by reference.

### BACKGROUND

### Technical Field

The present disclosure relates to a solar cell module.

### Background Art

Japanese Unexamined Patent Application, Publication No. 2018-157175 and Japanese Unexamined Patent Application, Publication No. 2018-157176 each disclose a solar cell module including a perovskite-based (thin-film) solar cell submodule. The solar cell submodule includes a plurality of perovskite-based (thin-film) solar cells that are separated from each other in a first direction (integration direction) on a single transparent substrate, extend in a second direction intersecting the first direction, and are connected in series and integrated. The solar cell includes a first transparent electrode layer, a first conductivity type charge transport layer, a photoelectric conversion layer, a second conductivity type charge transport layer, and a second electrode layer in this order from the transparent substrate side.

### SUMMARY

In the solar cell submodule having such an integrated structure, since the current is high and the resistance loss in the transparent electrode layer is large, the width of the solar cell is reduced. In this case, the number of stages of the integrated structure increases, and the voltage increases.

In this regard, in the solar cell submodule of the integrated structure, it is conceivable to form two solar cell submodules line-symmetrically (double door configuration) in the first direction (integration direction), connect the centers to each other, connect the ends to each other, and connect them in parallel. In the case where two solar cell submodules are formed line-symmetrically (double door configuration) as described above, in the solar cells adjacent to each other in the center, the second electrode layers on the side far from the transparent substrate are connected to each other as shown, for example, in FIG. 4 of the present application.

However, in this case, the solar cells adjacent to each other in the center are non-power generation regions from which power cannot be extracted. In the case where solar cell submodules are formed on a single transparent substrate, it is preferable that the non-power generation region is not formed in the center because the power generation efficiency is higher in the center than in the ends, for example, for the reason of film formation.

Accordingly, the present disclosure provides a solar cell module in which no non-power generation region is formed in the center.

A solar cell module according to the present disclosure includes a first thin-film solar cell submodule and a second thin-film solar cell submodule adjacent to each other in a first direction on a transparent substrate. The first thin-film solar cell submodule has a first integrated structure in which a plurality of first thin-film solar cells separated from each other in the first direction and extending in a second direction intersecting the first direction are connected in series in the first direction. The second thin-film solar cell submodule has a second integrated structure in which a plurality of second thin-film solar cells separated from each other in the first direction and extending in the second direction are connected in series in the first direction. Each of the plurality of first thin-film solar cells and each of the plurality of second thin-film solar cells includes a first transparent electrode layer, a first conductivity type charge transport layer, a photoelectric conversion layer, a second conductivity type charge transport layer, and a second electrode layer in this order from a transparent substrate side. The first integrated structure and the second integrated structure each include a first separation groove, a second separation groove, and a third separation groove that extend in the second direction. The first separation groove separates the first transparent electrode layer in the first direction. The second separation groove separates the second conductivity type charge transport layer, the photoelectric conversion layer, and the first conductivity type charge transport layer in the first direction. The third separation groove separates the second electrode layer in the first direction. The first integrated structure and the second integrated structure have a structure that is symmetrical with respect to a straight line along the second direction. The third separation groove, the second separation groove, and the first separation groove are arranged in this order from a center between the first integrated structure and the second integrated structure toward each end.

According to the present disclosure, no non-power generation region is formed in the center of a solar cell module.

### BRIEF DESCRIPTION OF THE DRAWINGS

FIG. 1 is a schematic cross-sectional view of a solar cell module according to a first embodiment;

FIG. 2 is a schematic cross-sectional view of solar cell submodules in the solar cell module shown in FIG. 1;

FIG. 3 is a schematic plan view showing the solar cell submodules in the solar cell module shown in FIG. 1 from the back surface side;

FIG. 4 is a schematic cross-sectional view of solar cell submodules in a solar cell module according to a comparative example;

FIG. 5 is a schematic cross-sectional view of a solar cell module according to a second embodiment;

FIG. 6 is a schematic cross-sectional view of solar cell submodules in the solar cell module shown in FIG. 5; and

FIG. 7 is a schematic plan view showing the solar cell submodules in the solar cell module shown in FIG. 5 from the back surface side.

### DETAILED DESCRIPTION

Hereinafter, an exemplary embodiment of the present disclosure will be described with reference to the accompanying drawings. In the drawings, the same or corresponding portions are denoted by the same reference numerals. Hatching, member reference numerals, and the like may be omitted for convenience, but in such a case, other drawings will be referred to.

### First Embodiment

### (Solar Cell Module)

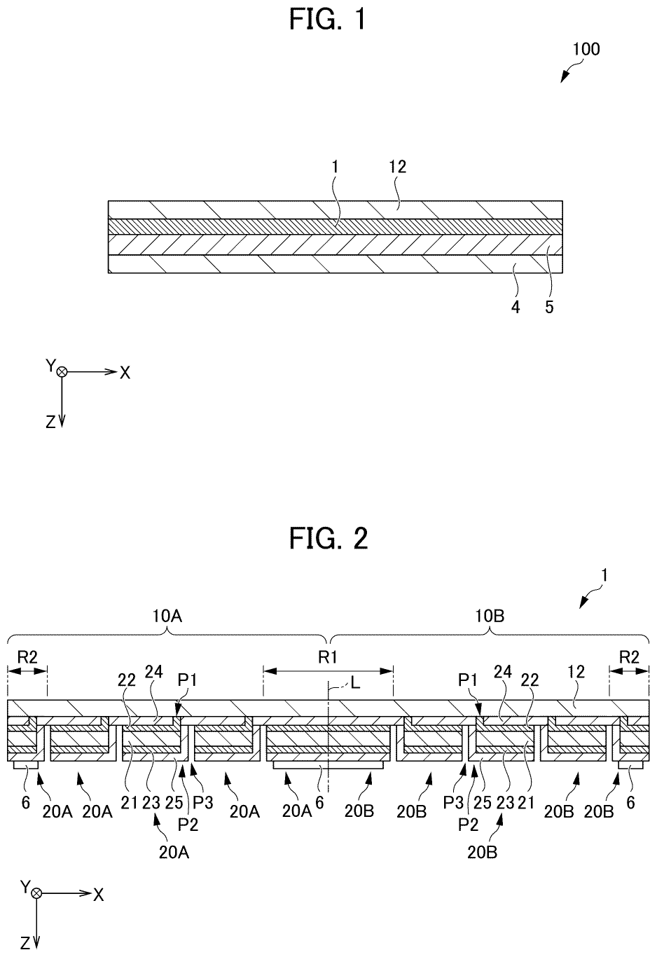

FIG. 1 is a schematic cross-sectional view of a solar cell module according to a first embodiment. A solar cell module 100 shown in FIG. 1 includes a thin-film solar cell submodule 1. Details of the solar cell submodule 1 will be described later.

The solar cell submodule 1 is sandwiched between a single transparent substrate 12 of the solar cell submodule 1 described later and a back side protection member 4. A liquid or solid sealing material 5 is filled between the transparent substrate 12 of the solar cell submodule 1 and the back side protection member 4, whereby the solar cell submodule 1 is sealed.

The sealing material 5 seals and protects the solar cell submodule 1, and is interposed between the back side surface of the solar cell submodule 1 and the back side protection member 4. The shape of the sealing material 5 is not particularly limited, and examples thereof include a sheet shape. This is because a sheet-shaped material can easily cover the surface of the planar solar cell submodule 1.

The material for the sealing material 5 is not particularly limited, but it is preferable that the material has a property of transmitting light (translucency). In addition, it is preferable that the material for the sealing material 5 has adhesiveness for bonding the solar cell submodule 1 and the back side protection member 4. Examples of such a material include translucent resins such as ethylene/vinyl acetate copolymer (EVA), ethylene/α-olefin copolymer, ethylene/vinyl acetate/triallylisocyanurate (EVAT), polyvinyl butyrate (PVB), acrylic resin, urethane resin, and silicone resin.

The back side protection member 4 covers the back surface of the solar cell submodule 1 via the sealing material 5 to protect the solar cell submodule 1. The shape of the back side protection member 4 is not particularly limited, but is preferably a plate shape or a sheet shape from the viewpoint of indirectly covering the planar back surface.

The material for the back side protection member 4 is not particularly limited, but is preferably a material that prevents intrusion of water or the like (i.e., has a high water-shielding property). For example, a resin film such as polyethylene terephthalate (PET), polyethylene (PE), an olefin-based resin, a fluorine-containing resin, or a silicone-containing resin, or a laminate of a plate-shaped resin member having translucency such as glass, polycarbonate, or acrylic and a metal foil such as an aluminum foil may be used. When the material for the back side protection member 4 is a resin, a barrier film that prevents water vapor from passing therethrough may be provided on the front surface or the back surface of the back side protection member 4. This allows the solar cell submodule 1 to be protected from water vapor.

### (Solar Cell Submodule)

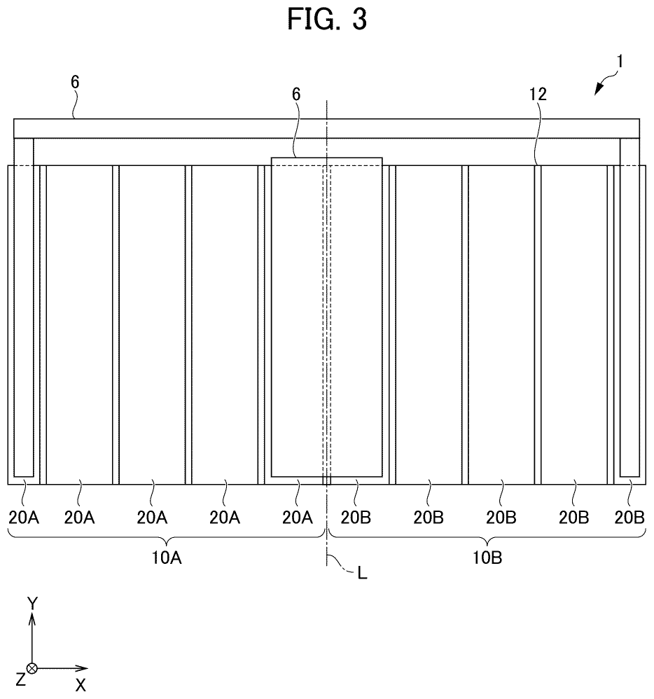

FIG. 2 is a schematic cross-sectional view of the solar cell submodule 1 in the solar cell module 100 shown in FIG. 1, and FIG. 3 is a schematic plan view showing the solar cell submodule 1 in the solar cell module 100 shown in FIG. 1 from the back surface side.

As shown in FIGS. 2 and 3, the solar cell submodule 1 includes a first thin-film solar cell submodule 10A and a second thin-film solar cell submodule 10B that are adjacent to each other in a first direction (X direction) on the single transparent substrate 12. Each of the first thin-film solar cell submodule 10A and the second thin-film solar cell submodule 10B includes a thin-film solar cell such as an inorganic semiconductor thin film, an organic semiconductor thin film, or an organic-inorganic hybrid semiconductor thin film, for example, an amorphous silicon-based solar cell or a perovskite-based solar cell.

The first thin-film solar cell submodule 10A includes a plurality of first thin-film solar cells 20A that are separated from each other in the X direction (integration direction: first direction) on the transparent substrate 12, extend in a Y direction (second direction) intersecting the X direction, and are connected in series and integrated (first integrated structure). The second thin-film solar cell submodule 10B includes a plurality of second thin-film solar cells 20B that are separated from each other in the X direction (integration direction: first direction) on the transparent substrate 12, extend in the Y direction (second direction) intersecting the X direction, and are connected in series and integrated (second integrated structure). This enables the conductive distance in the X direction to be shortened and the amount of current per one solar cell 20A, 20B to be reduced, and as a result, the resistance loss due to electrode layers 24 and 25, particularly, the electrode layers 24 and 25 including transparent electrodes (ITO) can be reduced.

The transparent substrate 12 is, for example, a flat plate-shaped or film-shaped substrate. Examples of the material for the transparent substrate 12 include polyethylene terephthalate (PET), polyethylene naphthalate (PEN), polyimide (PI), and glass.

Hereinafter, thin-film solar cell submodules 10A and 10B including perovskite-based solar cells as the thin-film solar cells 20A and 20B will be exemplified. Each of the thin-film solar cells 20A and 20B includes a perovskite layer 21 as a photoelectric conversion layer, charge transport layers 22 and 23, and electrode layers 24 and 25.

The perovskite layer 21 is a photoelectric conversion layer, and absorbs light to generate photocarriers. The compound constituting the perovskite-type crystal material is represented by the general formula R¹NH₃M¹X₃ or HC(NH₂)₂M¹X₃. In the formula, R¹ represents an alkyl group, preferably an alkyl group having 1 to 5 carbon atoms, and particularly preferably a methyl group. M¹ is a divalent metal ion, and Pb or Sn is preferable. X is halogen, and examples thereof include F, Cl, Br, and I. The three Xs may all be the same halogen element, or a plurality of halogens may be mixed.

Preferable examples of the compound constituting the perovskite-type crystal material include compounds represented by the formula CH₃NH₃Pb(I₁₋ₓBrₓ)₃ (where 0≤x≤1). The spectral sensitivity characteristic of the perovskite material can be changed by changing the type or ratio of halogens. The perovskite thin film can be formed by various dry processes or solution film formation such as spin coating, die coating, or inkjet printing.

One of the charge transport layers 22 and 23 is a hole transport layer, and the other is an electron transport layer. Examples of the material for the hole transport layer include polythiophene derivatives such as poly-3-hexylthiophene (P3HT) and poly(3,4-ethylenedioxythiophene) (PEDOT), fluorene derivatives such as 2,2′,7,7′-tetrakis-(N, N-di-p-methoxyphenylamine)-9,9′-spirobifluorene (Spiro-OMeTAD), carbazole derivatives such as polyvinylcarbazole, triphenylamine derivatives, diphenylamine derivatives, polysilane derivatives, and polyaniline derivatives.

Examples of the material for the electron transport layer include metal oxides such as titanium oxide, zinc oxide, niobium oxide, zirconium oxide, and aluminum oxide.

The electrode layer 24 for extracting photogenerated carriers is formed on the charge transport layer 22 side of the thin-film solar cells 20A and 20B. The electrode layer 25 for extracting photogenerated carriers is formed on the charge transport layer 23 side of the thin-film solar cells 20A and 20B.

The electrode layer 24 may include a transparent electrode layer. The electrode layer 25 may include a transparent electrode layer and a metal electrode layer, may include only a transparent electrode layer, or may include only a metal electrode layer. As the material for the transparent electrode layer, a metal oxide such as ITO, zinc oxide, or tin oxide is preferably used. As the material for the metal electrode layer, silver, copper, aluminum, or the like is preferably used.

### (First Thin-Film Solar Cell Submodule and Second Thin-Film Solar Cell Submodule)

The first thin-film solar cell submodule 10A (first integrated structure) and the second thin-film solar cell submodule 10B (second integrated structure) are arranged line-symmetrically with respect to a straight line L along the Y direction (second direction) (double door structure). In the present application, the term “line symmetry” includes not only a completely symmetric form but also a form that is somewhat asymmetric but can be recognized as being substantially symmetric. This facilitates parallel connection of the first thin-film solar cell submodule 10A (first integrated structure) and the second thin-film solar cell submodule 10B (second integrated structure) formed on the single transparent substrate 12.

Specifically, the second electrode layer 25 (electrode layer on the side far from the transparent substrate 12) of the first thin-film solar cell 20A on the second thin-film solar cell submodule 10B side (center side) of the first thin-film solar cell submodule 10A, and the second electrode layer 25 (electrode layer on the side far from the transparent substrate 12) of the second thin-film solar cell 20B on the first thin-film solar cell submodule 10A side of the second thin-film solar cell submodule 10B, are connected by a wiring member 6. The second electrode layer 25 (electrode layer on the side far from the transparent substrate 12) of the first thin-film solar cell 20A on the side (end side) of the first thin-film solar cell submodule 10A opposite to the second thin-film solar cell submodule 10B, and the second electrode layer 25 (electrode layer on the side far from the transparent substrate 12) of the second thin-film solar cell 20B on the side (end side) of the second thin-film solar cell submodule 10B opposite to the first thin-film solar cell submodule 10A, are connected by the wiring member 6.

The first thin-film solar cell submodule 10A (first integrated structure) and the second thin-film solar cell submodule 10B (second integrated structure) each include a first separation groove P1, a second separation groove P2, and a third separation groove P3 that extend in the Y direction (second direction).

The first separation groove P1 separates the electrode layer (first transparent electrode layer) 24 in the X direction (integration direction, first direction). The first separation groove P1 has a depth corresponding to the thickness of the electrode layer 24 in the stacking direction, and is filled with the material of the charge transport layer (first conductivity type charge transport layer) 22.

The second separation groove P2 separates the charge transport layer (second conductivity type charge transport layer) 23, a photoelectric conversion layer 21, and the charge transport layer (first conductivity type charge transport layer) 22 in the X direction (integration direction, first direction). The second separation groove P2 has a depth corresponding to the thicknesses of the charge transport layer 23, the photoelectric conversion layer 21, and the charge transport layer 22 in the stacking direction, and is filled with the material of the electrode layer 25.

The third separation groove P3 separates the electrode layer (second electrode layer) 25 in the X direction (integration direction, first direction). The third separation groove P3 has a depth corresponding to the thicknesses of the electrode layer 25, the charge transport layer 23, the photoelectric conversion layer 21, and the charge transport layer 22 in the stacking direction.

In the X direction (integration direction, first direction), the third separation groove P3, the second separation groove P2, and the first separation groove P1 are arranged in this order from the center between the first thin-film solar cell submodule 10A (first integrated structure) and the second thin-film solar cell submodule 10B (second integrated structure) toward each end.

Thus, the first thin-film solar cell 20A (first thin-film solar cell 20A in a central region R1) on the second thin-film solar cell submodule 10B side (center side) of the first thin-film solar cell submodule 10A, and the second thin-film solar cell 20B (second thin-film solar cell 20B in the central region R1) on the first thin-film solar cell submodule 10A side (center side) of the second thin-film solar cell submodule 10B, are power generation regions from which power can be extracted. On the other hand, the first thin-film solar cell 20A (first thin-film solar cell 20A in an end region R2) on the side (end side) of the first thin-film solar cell submodule 10A opposite to the second thin-film solar cell submodule 10B, and the second thin-film solar cell 20B (second thin-film solar cell 20B in the end region R2) on the side (end side) of the second thin-film solar cell submodule 10B opposite to the first thin-film solar cell submodule 10A, are non-power generation regions in which power cannot be extracted.

In the first thin-film solar cell submodule 10A, the width in the X direction (integration direction, first direction) of the first thin-film solar cell 20A (first thin-film solar cell 20A in the end region R2) on the side (end side) opposite to the second thin-film solar cell submodule 10B is smaller than the width in the X direction of the other first thin-film solar cells 20A outside the end region R2. For example, the width in the X direction of the first thin-film solar cell 20A on the end side may be one-half the width in the X direction of the other first thin-film solar cells 20A.

In the second thin-film solar cell submodule 10B, the width in the X direction of the second thin-film solar cell 20B (second thin-film solar cell 20B in the end region R2) on the side (end side) opposite to the first thin-film solar cell submodule 10A is smaller than the width in the X direction of the other second thin-film solar cells 20B outside the end region R2. For example, the width in the X direction of the second thin-film solar cell 20B on the end side may be one-half the width in the X direction of the other second thin-film solar cells 20B.

This allows the non-power generation region on the end side to be narrowed as much as possible. Additionally, the electrode width on the center side where the current is concentrated can be made wider, and current limitation can be prevented.

Although FIG. 2 shows an example in which the separation groove P3 is not formed between the adjacent solar cells on the center side, the separation groove P3 may be formed between the adjacent solar cells on the center side. As a result, the separation grooves P3 are formed at equal intervals even on the center side, so that the appearance can be made uniform. On the other hand, when the separation groove P3 is not formed between the adjacent solar cells on the center side, the output of the solar cell module can be increased.

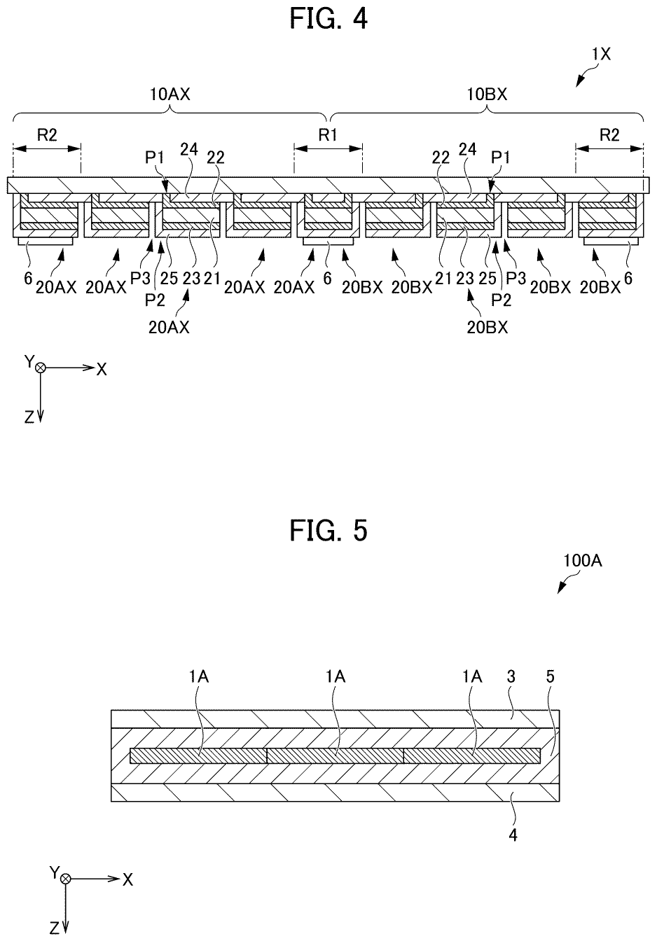

Here, FIG. 4 is a schematic cross-sectional view of a solar cell submodule 1X in a solar cell module according to a comparative example. In the solar cell submodule 1X having such an integrated structure, since the current is high and the resistance loss in transparent electrode layers 24 and 25 is large, the widths of solar cells 20AX and 20BX are reduced. In this case, the number of stages of the integrated structure increases, and the voltage increases.

In this regard, in the solar cell submodule 1X having the integrated structure, it is conceivable that two solar cell submodules 10AX and 10BX are formed line-symmetrically (double door configuration) in the X direction (integration direction, first direction), the centers are connected to each other, the ends are connected to each other, and the solar cell submodules are connected in parallel to each other. In the case where the two solar cell submodules 10AX and 10BX are formed line-symmetrically (double door configuration) as described above, in the solar cells 20AX and 20BX adjacent to each other in the center, the second electrode layers 25 on the side far from the transparent substrate 12 are connected to each other.

However, in this case, the solar cells 20AX and 20BX adjacent to each other in the center (solar cells 20AX and 20BX in the central region R1) become non-power generation regions from which power cannot be extracted. In the case where the solar cell submodule is formed on the single transparent substrate 12, since the power generation efficiency is higher in the center than in the end, it is preferable not to form the non-power generation region in the center.

Here, in the solar cell submodule 1X of the comparative example, the first separation groove P1, the second separation groove P2, and the third separation groove P3 are arranged in this order from the center between the first thin-film solar cell submodule 10AX (first integrated structure) and the second thin-film solar cell submodule 10BX (second integrated structure) toward each end in the X direction (integration direction, first direction).

In contrast, according to the solar cell submodule 1 of the solar cell module 100 of the present embodiment shown in FIG. 2, the third separation groove P3, the second separation groove P2, and the first separation groove P1 are arranged in this order from the center between the first thin-film solar cell submodule 10A (first integrated structure) and the second thin-film solar cell submodule 10B (second integrated structure) toward each end in the X direction (integration direction, first direction). Accordingly, the solar cells 20A and 20B adjacent to each other in the center (solar cells 20A and 20B in the central region R1) become power generation regions from which power can be extracted. As described above, since the solar cells 20A and 20B adjacent to each other in the center where the power generation efficiency is high are power generation regions, that is, no non-power generation regions are formed in the center where the power generation efficiency is high, the amount of power generation by the solar cell submodule 1 and the solar cell module 100 can be increased.

### Second Embodiment

### (Solar Cell Module)

FIG. 5 is a schematic cross-sectional view of a solar cell module according to a second embodiment. As shown in FIG. 5, a solar cell module 100A of a second embodiment differs from the solar cell module 100 of the first embodiment in that a plurality of solar cell submodules 1A are included instead of the solar cell submodule 1, and a light-receiving side protection member 3 is included.

The solar cell submodules 1A are sandwiched between the light-receiving side protection member 3 and a back side protection member 4. A liquid or solid sealing material 5 is filled between the light-receiving side protection member 3 and the back side protection member 4, thereby sealing the solar cell submodules 1A.

As described above, the sealing material 5 seals and protects the solar cell submodules 1A, and is interposed between the back side surfaces of the solar cell submodules 1A and the back side protection member 4, and is also interposed between the light-receiving side surfaces of the solar cell submodules 1A and the light-receiving side protection member 3.

The light-receiving side protection member 3 covers the surfaces (light-receiving surfaces) of the solar cell submodules 1 via the sealing material 5 to protect the solar cell submodules 1A. The shape of the light-receiving side protection member 3 is not particularly limited, but is preferably a plate shape or a sheet shape from the viewpoint of indirectly covering the planar light-receiving surfaces, similarly to the back side protection member 4.

The material for the light-receiving side protection member 3 is not particularly limited, but is preferably a material having a light-transmitting property and resistance to ultraviolet light similarly to the sealing material 5, and for example, glass or transparent resin such as acrylic resin or polycarbonate resin can be used. The surface of the light-receiving side protection member 3 may be processed unevenly or may be covered with an antireflection coating layer. With this configuration, the light-receiving side protection member 3 makes it difficult for the received light to be reflected, and thus allows more light to be guided to the solar cell submodule 1. When the material for the light-receiving side protection member 3 is resin, a barrier film that prevents water vapor from passing therethrough may be provided on the back surface or the front surface of the light-receiving side protection member 3. Thus, the solar cell submodules 1 can be protected from water vapor.

### (Solar Cell Submodule)

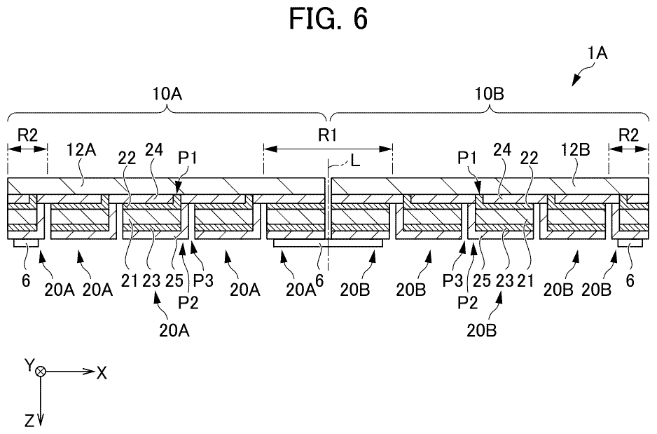

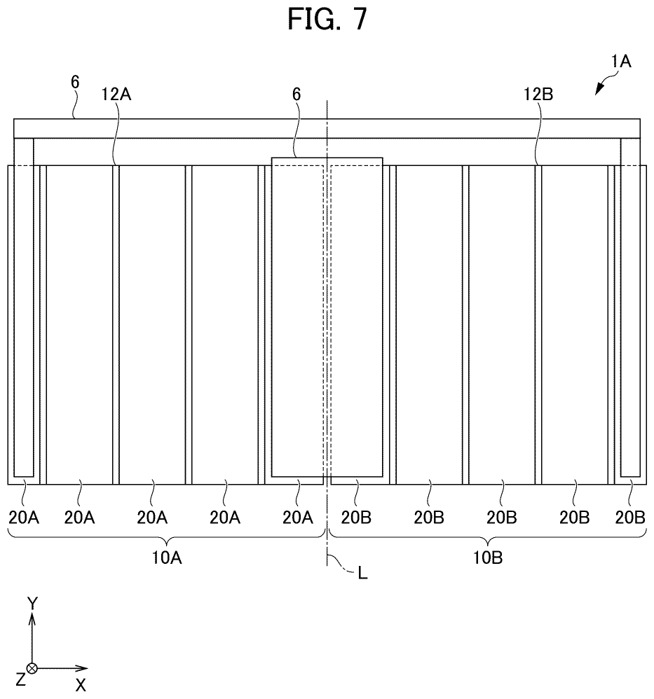

FIG. 6 is a schematic cross-sectional view of the solar cell submodule 1A in the solar cell module 100A shown in FIG. 5, and FIG. 7 is a schematic plan view showing the solar cell submodule 1A in the solar cell module 100A shown in FIG. 5 from the back surface side.

As shown in FIGS. 6 and 7, the solar cell submodule 1A of the second embodiment differs from the solar cell submodule 1 of the first embodiment in that a first thin-film solar cell submodule 10A and a second thin-film solar cell submodule 10B are formed on different transparent substrates 12A and 12B, respectively. Specifically, the solar cell submodule 1A includes, as transparent substrates, a first transparent substrate 12A and a second transparent substrate 12B separated from each other, the first thin-film solar cell submodule 10A is formed on the first transparent substrate 12A, and the second thin-film solar cell submodule 10B is formed on the second transparent substrate 12B.

Since the solar cell submodule 1A in the solar cell module 100A of the second embodiment also has the same features as those of the solar cell submodule 1 in the solar cell module 100 of the first embodiment, the same advantages as those of the solar cell submodule 1 in the solar cell module 100 of the first embodiment can be obtained.

In general, in a thin-film solar cell submodule, it is difficult to form a uniform film over a large area, for example, in a coating process for forming a photoelectric conversion layer. In this regard, according to the second embodiment, since the first thin-film solar cell submodule 10A and the second thin-film solar cell submodule 10B are formed on different transparent substrates 12A and 12B, respectively, a uniform film can be formed in a relatively small area.

Although the embodiments of the present disclosure have been described above, the present disclosure is not limited to the above-described embodiments, and various modifications and variations are possible. For example, in the first thin-film solar cell submodule 10A of the above-described embodiments, the width in the X direction (integration direction, first direction) of the first thin-film solar cell 20A (first thin-film solar cell 20A in the central region R1) on the second thin-film solar cell submodule 10B side (center side) may be greater than the width in the X direction of the other first thin-film solar cells 20A outside the central region R1. For example, the width in the X direction of the first thin-film solar cell 20A on the center side may be twice the width in the X direction of the other first thin-film solar cells 20A.

In the second thin-film solar cell submodule 10B of the above-described embodiments, the width in the X direction of the second thin-film solar cell 20B (second thin-film solar cell 20B in the central region R1) on the first thin-film solar cell submodule 10A side (center side) may be greater than the width in the X direction of the other second thin-film solar cells 20B outside the central region R1. For example, the width in the X direction of the second thin-film solar cell 20B on the center side may be twice the width in the X direction of the other second thin-film solar cells 20B.

As a result, in each of the first thin-film solar cell 20A and the second thin-film solar cell 20B on the center side, the area of the portion not covered by the wiring member 6 is increased, and power generation with respect to back-surface incident light can be improved. In the second embodiment, considering the processing tolerance of the substrate 12 made of glass or the like, it is conceivable that the widths of the first thin-film solar cell 20A and the second thin-film solar cell 20B on the center side are designed to be relatively large.

What is claimed is:

1. A solar cell module comprising:
a first thin-film solar cell submodule and a second thin-film solar cell submodule adjacent to each other in a first direction on a transparent substrate,
the first thin-film solar cell submodule having a first integrated structure in which a plurality of first thin-film solar cells separated from each other in the first direction and extending in a second direction intersecting the first direction are connected in series in the first direction,
the second thin-film solar cell submodule having a second integrated structure in which a plurality of second thin-film solar cells separated from each other in the first direction and extending in the second direction are connected in series in the first direction,
each of the plurality of first thin-film solar cells and each of the plurality of second thin-film solar cells comprising a first transparent electrode layer, a first conductivity type charge transport layer, a photoelectric conversion layer, a second conductivity type charge transport layer, and a second electrode layer in this order from a transparent substrate side,
the first integrated structure and the second integrated structure each comprising a first separation groove, a second separation groove, and a third separation groove that extend in the second direction, the first separation groove separating the first transparent electrode layer in the first direction, the second separation groove separating the second conductivity type charge transport layer, the photoelectric conversion layer, and the first conductivity type charge transport layer in the first direction, and the third separation groove separating the second electrode layer in the first direction,
the first integrated structure and the second integrated structure having a structure that is symmetrical with respect to a straight line along the second direction, and
the third separation groove, the second separation groove, and the first separation groove being arranged in this order from a center between the first integrated structure and the second integrated structure toward each end.

2. The solar cell module according to claim 1, wherein
the second electrode layer of a first thin-film solar cell on a second thin-film solar cell submodule side of the first thin-film solar cell submodule, and the second electrode layer of a second thin-film solar cell on a first thin-film solar cell submodule side of the second thin-film solar cell submodule, are connected by a wiring member, and
the second electrode layer of a first thin-film solar cell on a side of the first thin-film solar cell submodule opposite to the second thin-film solar cell submodule, and the second electrode layer of a second thin-film solar cell on a side of the second thin-film solar cell submodule opposite to the first thin-film solar cell submodule, are connected by a wiring member,
such that the first thin-film solar cell submodule and the second thin-film solar cell submodule are connected in parallel.

3. The solar cell module according to claim 1, wherein
a first thin-film solar cell on a second thin-film solar cell submodule side of the first thin-film solar cell submodule, and a second thin-film solar cell on a first thin-film solar cell submodule side of the second thin-film solar cell submodule, are power generation regions,
a first thin-film solar cell on a side of the first thin-film solar cell submodule opposite to the second thin-film solar cell submodule, and a second thin-film solar cell on a side of the second thin-film solar cell submodule opposite to the first thin-film solar cell submodule, are non-power generation regions,
in the first thin-film solar cell submodule, a width in the first direction of the first thin-film solar cell on the side opposite to the second thin-film solar cell submodule is smaller than a width in the first direction of another first thin-film solar cell, and
in the second thin-film solar cell submodule, a width in the first direction of the second thin-film solar cell on the side opposite to the first thin-film solar cell submodule is smaller than a width in the first direction of another second thin-film solar cell.

4. The solar cell module according to claim 3, wherein
in the first thin-film solar cell submodule, a width in the first direction of the first thin-film solar cell on the second thin-film solar cell submodule side is greater than a width in the first direction of another first thin-film solar cell, and
in the second thin-film solar cell submodule, a width in the first direction of the second thin-film solar cell on the first thin-film solar cell submodule side is greater than a width in the first direction of another second thin-film solar cell.

5. The solar cell module according to claim 1, wherein the transparent substrate is a single substrate.

6. The solar cell module according to claim 1, wherein
the transparent substrate comprises a first transparent substrate and a second transparent substrate separated from each other,
the first thin-film solar cell submodule is on the first transparent substrate, and
the second thin-film solar cell submodule is on the second transparent substrate.

7. The solar cell module according to claim 2, wherein
the transparent substrate is a single substrate.

8. The solar cell module according to claim 3, wherein
the transparent substrate is a single substrate.

9. The solar cell module according to claim 4, wherein
the transparent substrate is a single substrate.

10. The solar cell module according to claim 2, wherein
the transparent substrate comprises a first transparent substrate and a second transparent substrate separated from each other,
the first thin-film solar cell submodule is on the first transparent substrate, and
the second thin-film solar cell submodule is on the second transparent substrate.

11. The solar cell module according to claim 3, wherein
the transparent substrate comprises a first transparent substrate and a second transparent substrate separated from each other,
the first thin-film solar cell submodule is on the first transparent substrate, and
the second thin-film solar cell submodule is on the second transparent substrate.

12. The solar cell module according to claim 4, wherein
the transparent substrate comprises a first transparent substrate and a second transparent substrate separated from each other,
the first thin-film solar cell submodule is on the first transparent substrate, and
the second thin-film solar cell submodule is on the second transparent substrate.
